(19) United States
(12) Patent Application Publication
(10) Pub. No.: US 2011/0014746 A1
(43) Pub. Date: Jan. 20, 2011

(54) Semiconductor Device and Method of Forming Conductive TSV in Peripheral Region of Die Prior to Wafer Singulaton

(75) Inventors: Byung Tai Do, Singapore (SG); Reza A. Pagaila, Singapore (SG)

Correspondence Address: Robert D. Atkins, 605 W. Knox Road, Suite 104, Tempe, AZ, 85284, US

(73) Assignee: STATS CHIPPAC, LTD., Singapore (SG)

(21) Appl. No.: 12/505,273

(22) Filed: Jul. 17, 2009

(51) Int. Cl. H01L 21/98; H01L 21/78

(52) U.S. Cl. 438/107; 438/113; 257/E21.705; 257/E21.599

(57) ABSTRACT

A semiconductor device is made by providing a semiconductor wafer having semiconductor die separated by a peripheral region. An opening is formed in the peripheral region having a depth less than a thickness of the wafer. A conductive material is deposited in the opening of the peripheral region of the wafer to form a conductive via extending partially through the wafer. The wafer is singulated through the conductive via in the peripheral region to provide a plurality of semiconductor die each having the conductive via. A semiconductor die is mounted on a sacrificial carrier. An encapsulant is deposited over the carrier around the semiconductor die. A portion of the encapsulant and semiconductor die is removed to expose the conductive via. A first and second interconnect structure are formed over the encapsulant and semiconductor die. The first and second interconnect structures are electrically connected to the conductive via.

### FIELD OF THE INVENTION

The present invention relates in general to semiconductor devices and, more particularly, to a semiconductor device and method of forming conductive through silicon vias (TSV) in a peripheral region of the die prior to wafer singulation.

### BACKGROUND OF THE INVENTION

Semiconductor devices are commonly found in modern electronic products. Semiconductor devices vary in the number and density of electrical components. Discrete semiconductor devices generally contain one type of electrical component, e.g., light emitting diode (LED), small signal transistor, resistor, capacitor, inductor, and power metal oxide semiconductor field effect transistor (MOSFET). Integrated semiconductor devices typically contain hundreds to millions of electrical components. Examples of integrated semiconductor devices include microcontrollers, microprocessors, charged-coupled devices (CCDs), solar cells, and digital micro-mirror devices (DMDs).

Semiconductor devices perform a wide range of functions such as high-speed calculations, transmitting and receiving electromagnetic signals, controlling electronic devices, transforming sunlight to electricity, and creating visual projections for television displays. Semiconductor devices are found in the fields of entertainment, communications, power conversion, networks, computers, and consumer products. Semiconductor devices are also found in military applications, aviation, automotive, industrial controllers, and office equipment.

Semiconductor devices exploit the electrical properties of semiconductor materials. The atomic structure of semiconductor material allows its electrical conductivity to be manipulated by the application of an electric field or base current or through the process of doping. Doping introduces impurities into the semiconductor material to manipulate and control the conductivity of the semiconductor device.

A semiconductor device contains active and passive electrical structures. Active structures, including bipolar and field effect transistors, control the flow of electrical current. By varying levels of doping and application of an electric field or base current, the transistor either promotes or restricts the flow of electrical current. Passive structures, including resistors, capacitors, and inductors, create a relationship between voltage and current necessary to perform a variety of electrical functions. The passive and active structures are electrically connected to form circuits, which enable the semiconductor device to perform high-speed calculations and other useful functions.

Semiconductor devices are generally manufactured using two complex manufacturing processes, i.e., front-end manufacturing, and back-end manufacturing, each involving potentially hundreds of steps. Front-end manufacturing involves the formation of a plurality of die on the surface of a semiconductor wafer. Each die is typically identical and contains circuits formed by electrically connecting active and passive components. Back-end manufacturing involves singulating individual die from the finished wafer and packaging the die to provide structural support and environmental isolation.

One goal of semiconductor manufacturing is to produce smaller semiconductor devices. Smaller devices typically consume less power, have higher performance, and can be produced more efficiently. In addition, smaller semiconductor devices have a smaller footprint, which is desirable for smaller end products. A smaller die size may be achieved by improvements in the front-end process resulting in die with smaller, higher density active and passive components. Back-end processes may result in semiconductor device packages with a smaller footprint by improvements in electrical interconnection and packaging materials.

The electrical interconnection between a fan-out wafer level chip scale package (FO-WLCSP) containing semiconductor devices on multiple levels (3-D device integration) and external devices can be accomplished with conductive through silicon vias (TSV) or through hole vias (THV). To form TSVs or THVs, the semiconductor die is singulated from the wafer and placed on a sacrificial carrier. A via is cut through the semiconductor material or peripheral region around each semiconductor die while the die are mounted to the carrier. The vias are then filled with an electrically conductive material, for example, copper deposition through an electroplating process.

The TSV and THV formation typically involves considerable time for the via filling, which reduces the unit-per-hour (UPH) production schedule. The equipment needed for electroplating, e.g., plating bath, and sidewall passivation increases manufacturing cost. In addition, voids may be formed within the vias, which causes defects and reduces reliability of the device. TSV and THV can be a slow and costly approach to make vertical electrical interconnections in semiconductor packages. These interconnect schemes also have problems with production yield, large package size, and process cost management.

### SUMMARY OF THE INVENTION

A need exists for a low-cost vertical interconnect structure using a simplified manufacturing process. Accordingly, in one embodiment, the present invention is a method of making a semiconductor device comprising the steps of providing a semiconductor wafer having a plurality of semiconductor die separated by a peripheral region, forming an opening in the peripheral region having a depth less than a thickness of the semiconductor wafer, depositing a conductive material in the opening of the peripheral region of the semiconductor wafer to form a conductive via extending partially through the semiconductor wafer, singulating the semiconductor wafer through the conductive via in the peripheral region to provide a plurality of semiconductor die each having the conductive via, leading with a first end of the conductive via, mounting a first semiconductor die on a sacrificial carrier, depositing an encapsulant over the sacrificial carrier around the first semiconductor die, removing a portion of the encapsulant and first semiconductor die to expose a second end of the conductive via, and forming a first interconnect structure over the encapsulant and a first surface of the first semiconductor die. The first interconnect structure is electrically connected to the second end of the conductive via. The method further includes the steps of removing the sacrificial carrier, and forming a second interconnect structure over the encapsulant and a second surface of the first semiconductor die opposite the first surface of the first semiconductor die. The second interconnect structure is electrically connected to the first end of the conductive via.

In another embodiment, the present invention is a method of making a semiconductor device comprising the steps of providing a semiconductor wafer having a plurality of semiconductor components separated by a peripheral region, forming an opening in the peripheral region having a depth less than a thickness of the semiconductor wafer, depositing a conductive material in the opening of the peripheral region of the semiconductor wafer to form a conductive via, singulating the semiconductor wafer through the conductive via in the peripheral region to provide a plurality of semiconductor components each having the conductive via, mounting a first semiconductor component on a carrier, depositing an encapsulant over the carrier around the first semiconductor component, removing a portion of the encapsulant and first semiconductor component to expose the conductive via, and forming a first interconnect structure over the encapsulant and first semiconductor component. The first interconnect structure is electrically connected to the conductive via.

In another embodiment, the present invention is a method of making a semiconductor device comprising the steps of providing a semiconductor wafer having a plurality of semiconductor components separated by a peripheral region, forming an opening in the peripheral region having a depth less than a thickness of the semiconductor wafer, depositing a conductive material in the opening of the peripheral region of the semiconductor wafer to form a conductive via, singulating the semiconductor wafer through the conductive via in the peripheral region to provide a plurality of semiconductor components each having the conductive via, depositing an encapsulant around the first semiconductor component, and forming a first interconnect structure over the encapsulant and first semiconductor component. The first interconnect structure is electrically connected to the conductive via.

In another embodiment, the present invention is a method of making a semiconductor device comprising the steps of providing a semiconductor wafer having a plurality of semiconductor components separated by a peripheral region, forming an opening in the peripheral region having a depth less than a thickness of the semiconductor wafer, depositing a conductive material in the opening of the peripheral region of the semiconductor wafer to form a conductive via, and singulating the semiconductor wafer through the conductive via in the peripheral region to provide a plurality of semiconductor components each having the conductive via.

### BRIEF DESCRIPTION OF THE DRAWINGS

FIG. 1 illustrates a printed circuit board (PCB) with different types of packages mounted to its surface;

FIGS. 2a-2c illustrate further detail of the representative semiconductor packages mounted to the PCB;

FIGS. 3a-3j illustrate a process of forming a vertical interconnect structure for FO-WLCSP;

FIGS. 4a-4b illustrate the FO-WLCSP and vertical interconnect structure with a discrete electrical component;

FIGS. 5a-5b illustrate the FO-WLCSP and vertical interconnect structure with an RDL;

FIGS. 6a-6b illustrate the FO-WLCSP and vertical interconnect structure with a backside RDL;

FIG. 7 illustrates the FO-WLCSP and vertical interconnect structure with backside embedded interconnects;

FIG. 8 illustrates the FO-WLCSP and vertical interconnect structure with front-side interconnects; and

FIG. 9 illustrates the FO-WLCSP with an elongated vertical interconnect structure.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, resistors, and transformers, create a relationship between voltage and current necessary to perform electrical circuit functions.

Passive and active components are formed over the surface of the semiconductor wafer by a series of process steps including doping, deposition, photolithography, etching, and planarization. Doping introduces impurities into the semiconductor material by techniques such as ion implantation or thermal diffusion. The doping process modifies the electrical conductivity of semiconductor material in active devices, transforming the semiconductor material into an insulator, conductor, or dynamically changing the semiconductor material conductivity in response to an electric field or base current. Transistors contain regions of varying types and degrees of doping arranged as necessary to enable the transistor to promote or restrict the flow of electrical current upon the application of the electric field or base current.

Active and passive components are formed by layers of materials with different electrical properties. The layers can be formed by a variety of deposition techniques determined in part by the type of material being deposited. For example, thin film deposition may involve chemical vapor deposition (CVD), physical vapor deposition (PVD), electrolytic plating, and electroless plating processes. Each layer is generally patterned to form portions of active components, passive components, or electrical connections between components.

The layers can be patterned using photolithography, which involves the deposition of light sensitive material, e.g., photoresist, over the layer to be patterned. A pattern is transferred from a photomask to the photoresist using light. The portion of the photoresist pattern subjected to light is removed using a solvent, exposing portions of the underlying layer to be patterned. The remainder of the photoresist is removed, leaving behind a patterned layer. Alternatively, some types of materials are patterned by directly depositing the material into the areas or voids formed by a previous deposition/etch process using techniques such as electroless and electrolytic plating.

Depositing a thin film of material over an existing pattern can exaggerate the underlying pattern and create a non-uniformly flat surface. A uniformly flat surface is required to produce smaller and more densely packed active and passive components. Planarization can be used to remove material from the surface of the wafer and produce a uniformly flat surface. Planarization involves polishing the surface of the wafer with a polishing pad. An abrasive material and corrosive chemical are added to the surface of the wafer during polishing. The combined mechanical action of the abrasive and corrosive action of the chemical removes any irregular topography, resulting in a uniformly flat surface.

Back-end manufacturing refers to cutting or singulating the finished wafer into the individual die and then packaging the die for structural support and environmental isolation. To singulate the die, the wafer is scored and broken along non-functional regions of the wafer called saw streets or scribes. The wafer is singulated using a laser cutting tool or saw blade. After singulation, the individual die are mounted to a package substrate that includes pins or contact pads for interconnection with other system components. Contact pads formed over the semiconductor die are then connected to contact pads within the package. The electrical connections can be made with solder bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

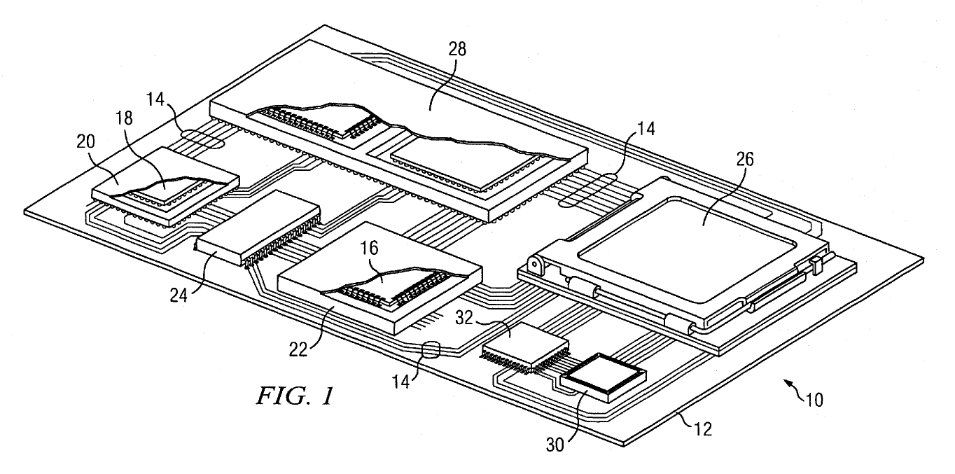

FIG. 1 illustrates electronic device 10 having a chip carrier substrate or printed circuit board (PCB) 12 with a plurality of semiconductor packages mounted on its surface. Electronic device 10 may have one type of semiconductor package, or multiple types of semiconductor packages, depending on the application. The different types of semiconductor packages are shown in FIG. 1 for purposes of illustration.

Electronic device 10 may be a stand-alone system that uses the semiconductor packages to perform one or more electrical functions. Alternatively, electronic device 10 may be a subcomponent of a larger system. For example, electronic device 10 may be a graphics card, network interface card, or other signal processing card that can be inserted into a computer. The semiconductor package can include microprocessors, memories, application specific integrated circuits (ASIC), logic circuits, analog circuits, RF circuits, discrete devices, or other semiconductor die or electrical components.

In FIG. 1, PCB 12 provides a general substrate for structural support and electrical interconnect of the semiconductor packages mounted on the PCB. Conductive signal traces 14 are formed over a surface or within layers of PCB 12 using evaporation, electrolytic plating, electroless plating, screen printing, or other suitable metal deposition process. Signal traces 14 provide for electrical communication between each of the semiconductor packages, mounted components, and other external system components. Traces 14 also provide power and ground connections to each of the semiconductor packages.

In some embodiments, a semiconductor device has two packaging levels. First level packaging is a technique for mechanically and electrically attaching the semiconductor die to an intermediate carrier. Second level packaging involves mechanically and electrically attaching the intermediate carrier to the PCB. In other embodiments, a semiconductor device may only have the first level packaging where the die is mechanically and electrically mounted directly to the PCB.

For the purpose of illustration, several types of first level packaging, including wire bond package 16 and flip chip 18, are shown on PCB 12. Additionally, several types of second level packaging, including ball grid array (BGA) 20, bump chip carrier (BCC) 22, dual in-line package (DIP) 24, land grid array (LGA) 26, multi-chip module (MCM) 28, quad flat non-leaded package (QFN) 30, and quad flat package 32, are shown mounted on PCB 12. Depending upon the system requirements, any combination of semiconductor packages, configured with any combination of first and second level packaging styles, as well as other electronic components, can be connected to PCB 12. In some embodiments, electronic device 10 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using cheaper components and a streamlined manufacturing process. The resulting devices are less likely to fail and less expensive to manufacture resulting in a lower cost for consumers.

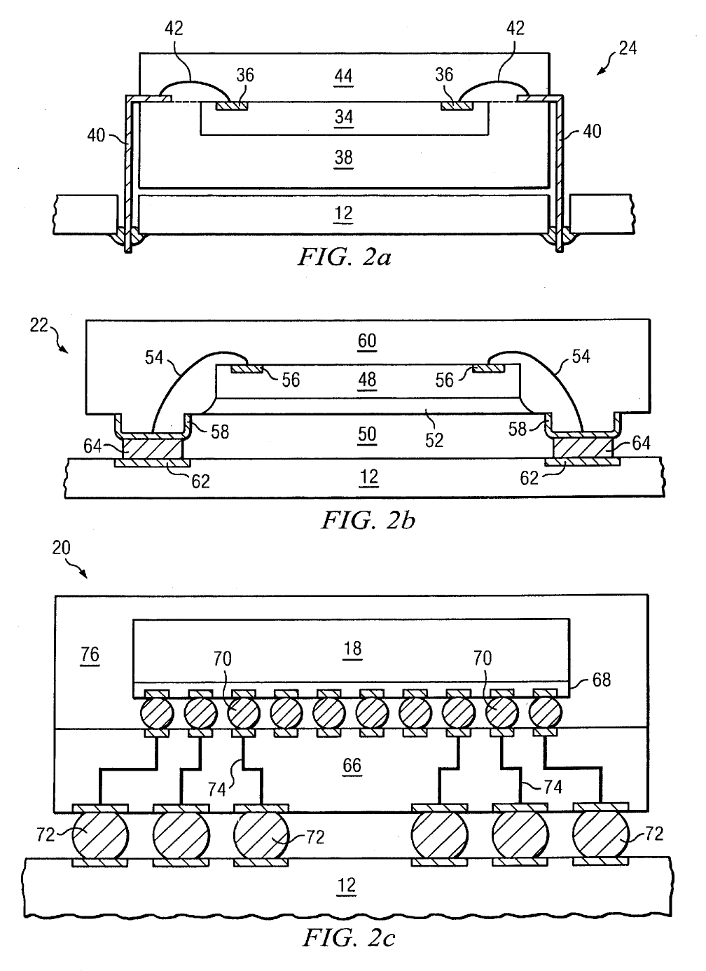

FIGS. 2a-2c show exemplary semiconductor packages. FIG. 2a illustrates further detail of DIP 24 mounted on PCB 12. Semiconductor die 34 includes an active region containing analog or digital circuits implemented as active devices, passive devices, conductive layers, and dielectric layers formed within the die and are electrically interconnected according to the electrical design of the die. For example, the circuit may include one or more transistors, diodes, inductors, capacitors, resistors, and other circuit elements formed within the active region of semiconductor die 34. Contact pads 36 are one or more layers of conductive material, such as aluminum (Al), copper (Cu), tin (Sn), nickel (Ni), gold (Au), or silver (Ag), and are electrically connected to the circuit elements formed within semiconductor die 34. During assembly of DIP 24, semiconductor die 34 is mounted to an intermediate carrier 38 using a gold-silicon eutectic layer or adhesive material such as thermal epoxy. The package body includes an insulative packaging material such as polymer or ceramic. Conductor leads 40 and wire bonds 42 provide electrical interconnect between semiconductor die 34 and PCB 12. Encapsulant 44 is deposited over the package for environmental protection by preventing moisture and particles from entering the package and contaminating die 34 or wire bonds 42.

FIG. 2b illustrates further detail of BCC 22 mounted on PCB 12. Semiconductor die 48 is mounted over carrier 50 using an underfill or epoxy-resin adhesive material 52. Wire bonds 54 provide first level packing interconnect between contact pads 56 and 58. Molding compound or encapsulant 60 is deposited over semiconductor die 48 and wire bonds 54 to provide physical support and electrical isolation for the device. Contact pads 62 are formed over a surface of PCB 12 using a suitable metal deposition such electrolytic plating or electroless plating to prevent oxidation. Contact pads 62 are electrically connected to one or more conductive signal traces 14 in PCB 12. Bumps 64 are formed between contact pads 58 of BCC 22 and contact pads 62 of PCB 12.

In FIG. 2c, semiconductor die 18 is mounted face down to intermediate carrier 66 with a flip chip style first level packaging. Active region 68 of semiconductor die 18 contains analog or digital circuits implemented as active devices, passive devices, conductive layers, and dielectric layers formed according to the electrical design of the die. For example, the circuit may include one or more transistors, diodes, inductors, capacitors, resistors, and other circuit elements within active region 68. Semiconductor die 18 is electrically and mechanically connected to carrier 66 through bumps 70.

BGA 20 is electrically and mechanically connected to PCB 12 with a BGA style second level packaging using bumps 72. Semiconductor die 18 is electrically connected to conductive signal traces 14 in PCB 12 through bumps 70, signal lines 74, and bumps 72. A molding compound or encapsulant 76 is deposited over semiconductor die 18 and carrier 66 to provide physical support and electrical isolation for the device. The flip chip semiconductor device provides a short electrical conduction path from the active devices on semiconductor die 18 to conduction tracks on PCB 12 in order to reduce signal propagation distance, lower capacitance, and improve overall circuit performance. In another embodiment, the semiconductor die 18 can be mechanically and electrically connected directly to PCB 12 using flip chip style first level packaging without intermediate carrier 66.

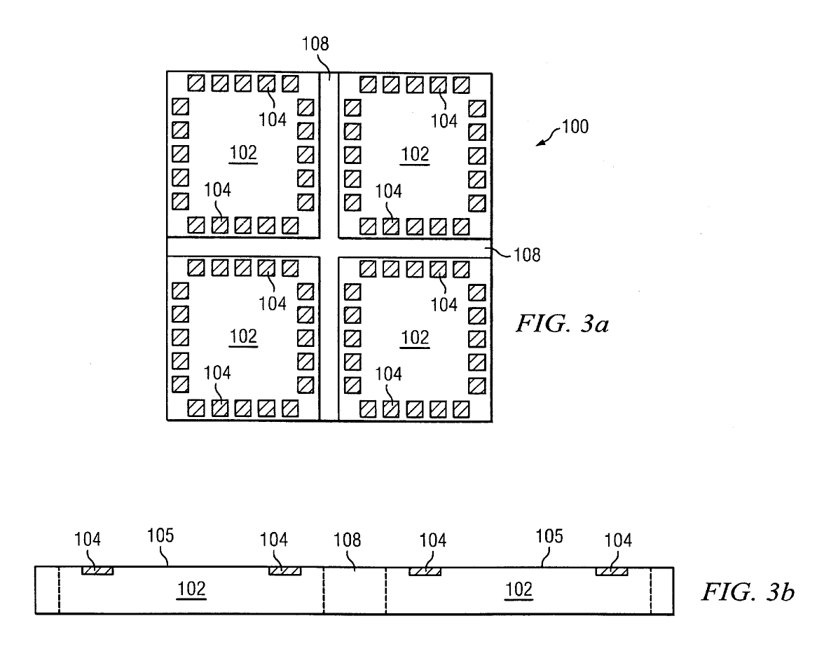

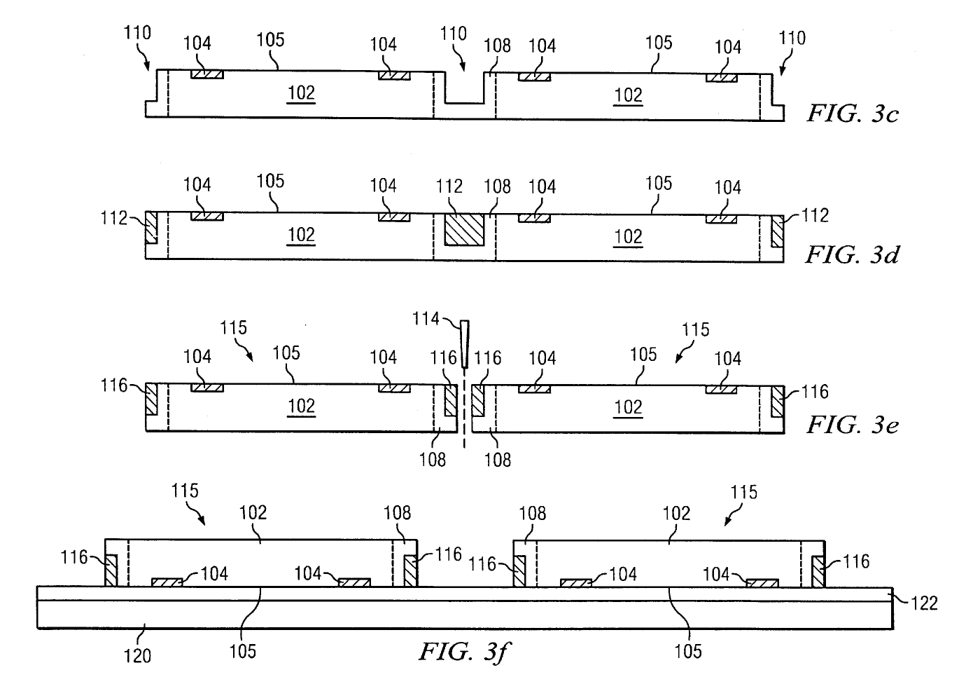

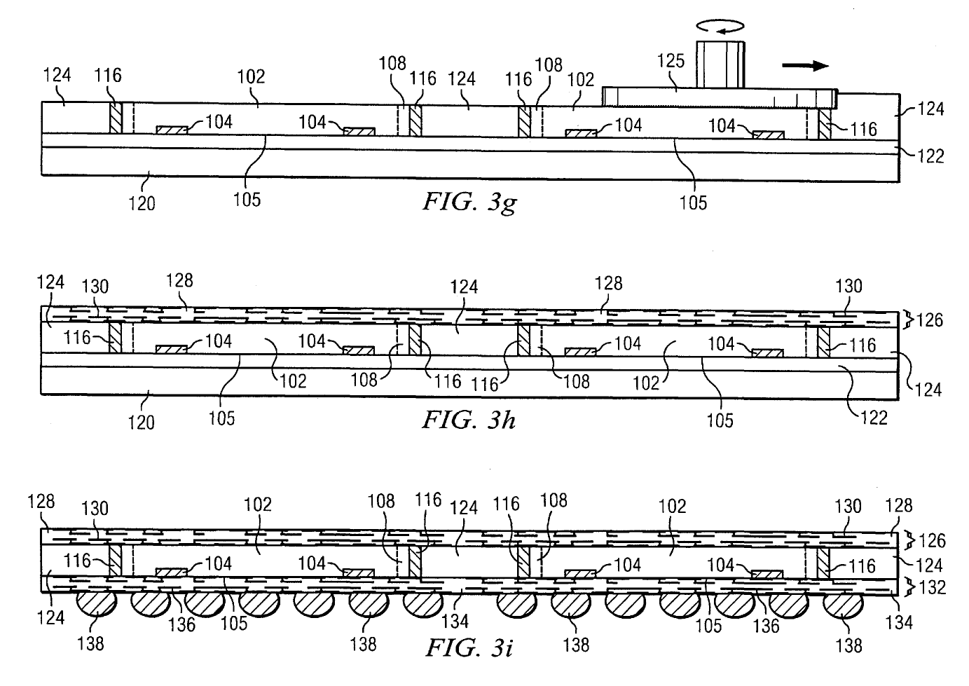

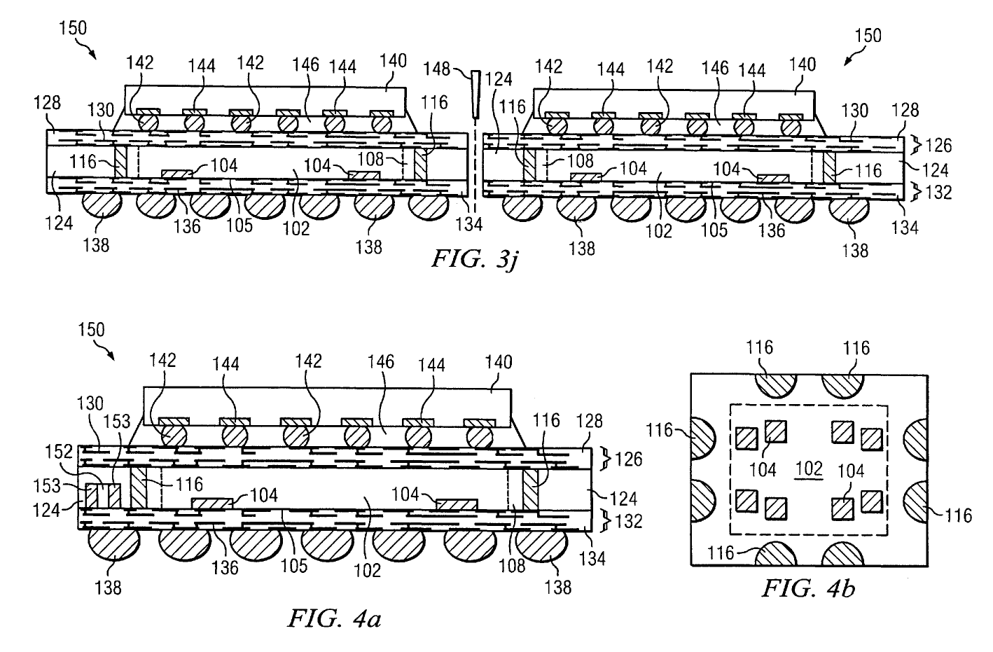

FIGS. 3a-3j illustrate a process of forming conductive vias in a peripheral region around a semiconductor die for a three dimensional (3-D) fan-out wafer level chip scale package (FO-WLCSP). To start the process, FIG. 3a shows a partial view of semiconductor wafer 100. A plurality of semiconductor die 102 are formed on semiconductor wafer 100 using conventional integrated circuit processes, as described above. Substrate 100 is made with a semiconductor base material such as silicon, germanium, gallium arsenide, indium phosphide, or silicon carbide.

Each semiconductor die or component 102 includes analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 105 to implement baseband analog circuits or digital circuits, such as digital signal processor (DSP), ASIC, memory, or other signal processing circuit. Semiconductor die 102 may also contain IPD, such as inductors, capacitors, and resistors, for RF signal processing. A typical RF system requires multiple IPDs in one or more semiconductor packages to perform the necessary electrical functions.

Semiconductor die 102 are separated by saw street 108, which constitute a peripheral region of the die. Contact pads 104 electrically connect to active and passive devices and signal traces in active area 105 of semiconductor die 102, as shown in FIG. 3b.

In FIG. 3c, a portion of the semiconductor base material in saw streets 108 is removed by laser drilling or deep reactive ion etching (DRIE) to create openings or holes 110 extending through substrate 100. In one embodiment, openings 110 extend partially through substrate 100, e.g., openings extend through 50% of the thickness of substrate 100. The sidewalls of openings 110 can be vertical or tapered.

In FIG. 3d, an electrically conductive material 112 is formed in openings 110 using patterning with PVD, CVD, electrolytic plating, electroless plating process, or other suitable metal deposition process. Conductive material 112 can be one or more layers of Al, Cu, Sn, Ni, Au, Ag, or other suitable electrically conductive material. The conductive material 112 in openings 110 form vertical, z-direction conductive through silicon vias (TSV) 116 in a peripheral region of semiconductor die 102 in wafer 100. Conductive TSVs 116 are formed in the peripheral region while semiconductor die 102 are still in wafer form, i.e., prior to wafer singulation.

Semiconductor substrate 100 is singulated in FIG. 3e using a laser cutting device or saw blade 114 into individual semiconductor packages 115.

In FIG. 3f, the semiconductor packages 115 are mounted to sacrificial substrate or carrier 120 with contact pads 104 and conductive TSVs 116 oriented face down over adhesive layer 122. Carrier 120 contains dummy or sacrificial base material such as silicon, polymer, polymer composite, metal, ceramic, glass, glass epoxy, beryllium oxide, or other suitable low-cost, rigid material or bulk semiconductor material for structural support.

FIG. 3g shows an encapsulant or molding compound 124 deposited over carriers 120 around semiconductor die 102 using a paste printing, compressive molding, transfer molding, liquid encapsulant molding, vacuum lamination, or other suitable applicator. Encapsulant 124 can be polymer composite material, such as epoxy resin with filler, epoxy acrylate with filler, or polymer with proper filler. Encapsulant 124 is planarized with grinder 125 to expose a back surface of semiconductor die 102, opposite active surface 105, and conductive TSVs 116. Encapsulant 124 is non-conductive and environmentally protects the semiconductor device from external elements and contaminants.

In FIG. 3h, a build-up interconnect structure 126 is formed over encapsulant 124 and the back surface of semiconductor die 102. The build-up interconnect structure 126 includes an insulating or passivation layer 128 containing one or more layers of silicon dioxide (SiO2), silicon nitride (Si3N4), silicon oxynitride (SiON), tantalum pentoxide (Ta2O5), aluminum oxide (Al2O3), or other material having similar insulating and structural properties. The insulating layers 128 are formed using PVD, CVD, printing, spin coating, spray coating, sintering with curing, or thermal oxidation.

The build-up interconnect structure 126 further includes an electrically conductive layer 130 formed in insulating layer 128 using patterning with PVD, CVD, sputtering, electrolytic plating, electroless plating process, or other suitable metal deposition process. Conductive layer 130 can be one or more layers of Al, Cu, Sn, Ni, Au, Ag, or other suitable electrically conductive material. One portion of conductive layer 130 electrically connects to conductive TSVs 116. Other portions of conductive layer 130 can be electrically common or electrically isolated depending on the design and function of the semiconductor device.

In FIG. 3i, carrier 120 and adhesive layer 122 are removed by chemical etching, mechanical peel-off, CMP, mechanical grinding, thermal bake, laser scanning, or wet stripping. Conductive TSVs 116 and active surface 105 of semiconductor die 102 are exposed following removal of carrier 120 and adhesive layer 122.

A build-up interconnect structure 132 is formed over encapsulant 124 and a front surface of semiconductor die 102. The build-up interconnect structure 132 includes an insulating or passivation layer 134 containing one or more layers of SiO2, Si3N4, SiON, Ta2O5, Al2O3, or other material having similar insulating and structural properties. The insulating layers 134 are formed using PVD, CVD, printing, spin coating, spray coating, sintering with curing, or thermal oxidation.

The build-up interconnect structure 132 further includes an electrically conductive layer 136 formed in insulating layers 134 using patterning with PVD, CVD, sputtering, electrolytic plating, electroless plating process, or other suitable metal deposition process. Conductive layer 136 can be one or more layers of Al, Cu, Sn, Ni, Au, Ag, or other suitable electrically conductive material. A portion of insulating layer 134 is removed by an etching process to expose conductive layer 136. One portion of conductive layer 136 electrically connects to conductive TSVs 116 and contact pads 104 of semiconductor die 102. Other portions of conductive layer 136 can be electrically common or electrically isolated depending on the design and function of the semiconductor device.

An electrically conductive bump material is deposited over conductive layer 136 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 136 using a suitable attachment or bonding process. In one embodiment, the bump material is reflowed by heating the material above its melting point to form spherical balls or bumps 138. In some applications, bumps 138 are reflowed a second time to improve electrical contact to conductive layer 136. The bumps can also be compression bonded to conductive layer 136. Bumps 138 represent one type of interconnect structure that can be formed over conductive layer 136. The interconnect structure can also use bond wires, stud bump, micro bump, or other electrical interconnect

In FIG. 3j, semiconductor die 140 is mounted to build-up interconnect structure 126. Semiconductor die 140 includes analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within the active surface to implement baseband analog circuits or digital circuits, such as DSP, ASIC, memory, or other signal processing circuit. Semiconductor die 102 may also contain IPD, such as inductors, capacitors, and resistors, for RF signal processing. A typical RF system requires multiple IPDs in one or more semiconductor packages to perform the necessary electrical functions. Solder bumps 142 electrically connect contact pads 144 to conductive layer 130. An underfill material 146 is deposited under semiconductor die 140. Semiconductor die 102 are singulated with saw blade or laser cutting device 148 into individual semiconductor devices 150.

FIG. 4a shows semiconductor package 150 after singulation. Conductive TSVs 116 formed in a peripheral region of semiconductor die 102 provide z-direction interconnect between interconnect build-up layers 126 and 132. FIG. 4b shows a top view of conductive TSVs 116 formed in a peripheral region around semiconductor die 102. The build-up interconnect structure 126 electrically connects through conductive TSVs 116 to build-up interconnect structure 132 and contact pads 104 of semiconductor die 102. By forming conductive TSVs 116 in a peripheral region of semiconductor die 102 while in wafer form, it is not necessary to form conductive vias while the die are mounted on the sacrificial carrier. The steps described in FIG. 3a-3j simplify the manufacturing process, lower cost, increase yield, and decrease semiconductor package size.

An electronic component 152 is mounted in the peripheral region of semiconductor die 102 and electrically connected to build-up interconnect structure 132, as seen in FIG. 4a. The electronic component 152 can be an IPD or discrete semiconductor device. Contact pads 153 of electrical component 152 electrically connect to conductive layer 136.

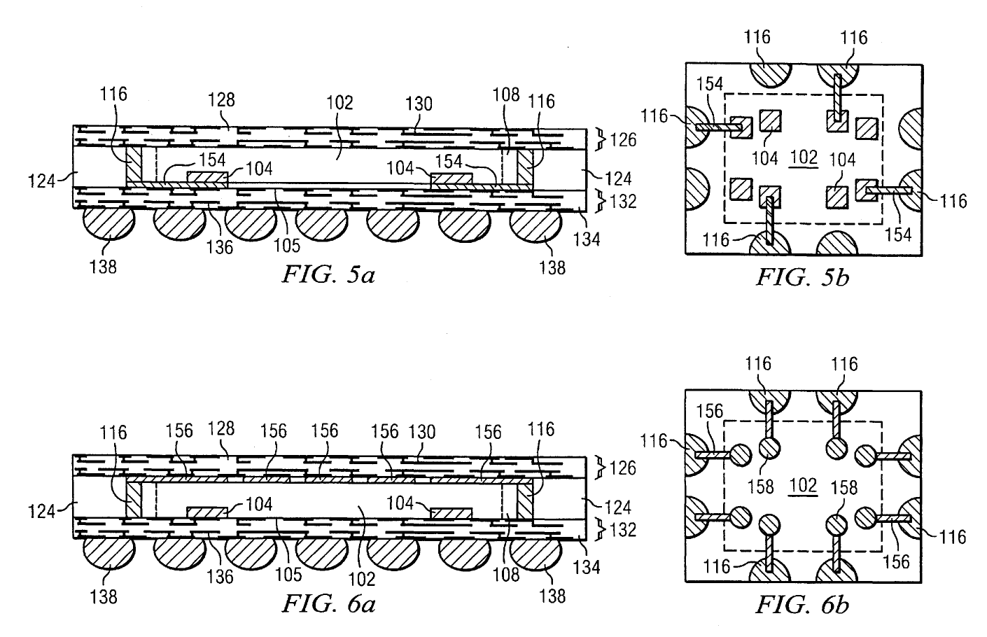

In FIG. 5a, an electrically conductive layer 154 is formed between conductive TSVs 116 and contact pads 104 of semiconductor die 102 using patterning with PVD, CVD, sputtering, electrolytic plating, electroless plating process, or other suitable metal deposition process. Conductive layer 154 can be one or more layers of Al, Cu, Sn, Ni, Au, Ag, or other suitable electrically conductive material. Conductive layer 154 operates as a redistribution layer (RDL) or runner to extend the conductivity of TSV 116. FIG. 5b shows a top view of RDL 154 electrically connecting conductive TSVs 116 to contact pads 104 of semiconductor die 102.

In FIG. 6a, an electrically conductive layer 156 is formed over the back surface of semiconductor die 102 using patterning with PVD, CVD, sputtering, electrolytic plating, electroless plating process, or other suitable metal deposition process. Conductive layer 156 can be one or more layers of Al, Cu, Sn, Ni, Au, Ag, or other suitable electrically conductive material. Conductive layer 156 operates as an RDL or runner to extend the conductivity of TSV 116. FIG. 6b shows a top view of RDL 156 electrically connecting conductive TSVs 116 to bumps 158.

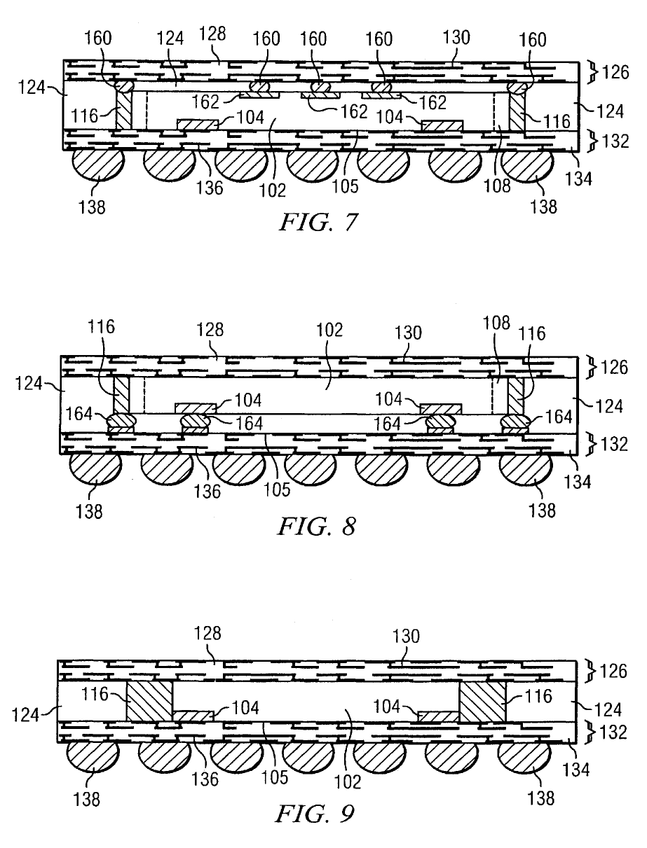

FIG. 7 shows embedded interconnects 160, e.g., e-SOP or stud bumps, formed over conductive layer 162 on the back surface of semiconductor die 102.

FIG. 8 shows embedded bumps 164 formed on a front surface of semiconductor die 102. Bumps 164 electrically connect conductive TSVs 116 and contact pads 104 to build-up interconnect structure 132.

FIG. 9 shows conductive TSVs 166 formed adjacent to contact pads 104 of semiconductor die 102. To form conductive TSVs 166, opening 110 is extended or elongated so that conductive material 112 directly connects to contact pad 104.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a semiconductor wafer having a plurality of semiconductor die separated by a peripheral region;
forming an opening in the peripheral region having a depth less than a thickness of the semiconductor wafer;
depositing a conductive material in the opening of the peripheral region of the semiconductor wafer to form a conductive via extending partially through the semiconductor wafer;
singulating the semiconductor wafer through the conductive via in the peripheral region to provide a plurality of semiconductor die each having the conductive via;
leading with a first end of the conductive via, mounting a first semiconductor die on a sacrificial carrier;
depositing an encapsulant over the sacrificial carrier around the first semiconductor die;
removing a portion of the encapsulant and first semiconductor die to expose a second end of the conductive via;
forming a first interconnect structure over the encapsulant and a first surface of the first semiconductor die, the first interconnect structure being electrically connected to the second end of the conductive via;
removing the sacrificial carrier; and
forming a second interconnect structure over the encapsulant and a second surface of the first semiconductor die opposite the first surface of the first semiconductor die, the second interconnect structure being electrically connected to the first end of the conductive via.

2. The method of claim 1, further including mounting a second semiconductor die over the first interconnect structure.

3. The method of claim 1, further including:
forming a first redistribution layer between the conductive via and a contact pad of the first semiconductor die; and
forming a second redistribution layer over the first surface of the first semiconductor die, the second redistribution layer being electrically connected to the conductive via.

4. The method of claim 1, further including:
forming a first bump between the first end of the conductive via and second interconnect structure; and
forming a second bump between the second surface of the first semiconductor die and first interconnect structure.

5. The method of claim 1, further including forming the conductive via adjacent to a contact pad of the first semiconductor die.

6. A method of making a semiconductor device, comprising:
providing a semiconductor wafer having a plurality of semiconductor components separated by a peripheral region;
forming an opening in the peripheral region having a depth less than a thickness of the semiconductor wafer;
depositing a conductive material in the opening of the peripheral region of the semiconductor wafer to form a conductive via;
singulating the semiconductor wafer through the conductive via in the peripheral region to provide a plurality of semiconductor components each having the conductive via;
mounting a first semiconductor component on a carrier;
depositing an encapsulant over the carrier around the first semiconductor component;
removing a portion of the encapsulant and first semiconductor component to expose the conductive via; and
forming a first interconnect structure over the encapsulant and first semiconductor component, the first interconnect structure being electrically connected to the conductive via.

7. The method of claim 6, further including:
removing the carrier; and
forming a second interconnect structure over the encapsulant and first semiconductor component opposite the first interconnect structure, the second interconnect structure being electrically connected to the conductive via.

8. The method of claim 7, further including forming a bump between the conductive via and second interconnect structure.

9. The method of claim 7, further including forming a bump between the first semiconductor die and first interconnect structure.

10. The method of claim 6, further including mounting a second semiconductor component over the first interconnect structure.

11. The method of claim 6, further including forming a redistribution layer between the conductive via and the first semiconductor component.

12. The method of claim 6, further including forming a redistribution layer between the first semiconductor component and first interconnect structure, the redistribution layer being electrically connected to the conductive via.

13. The method of claim 6, further including forming the conductive via adjacent to a contact pad of the first semiconductor component.

14. A method of making a semiconductor device, comprising:
providing a semiconductor wafer having a plurality of semiconductor components separated by a peripheral region;
forming an opening in the peripheral region having a depth less than a thickness of the semiconductor wafer;
depositing a conductive material in the opening of the peripheral region of the semiconductor wafer to form a conductive via;
singulating the semiconductor wafer through the conductive via in the peripheral region to provide a plurality of semiconductor components each having the conductive via;
depositing an encapsulant around the first semiconductor component; and
forming a first interconnect structure over the encapsulant and first semiconductor component, the first interconnect structure being electrically connected to the conductive via.

15. The method of claim 14, further including forming a second interconnect structure over the encapsulant and first semiconductor component opposite the first interconnect structure, the second interconnect structure being electrically connected to the conductive via.

16. The method of claim 15, further including forming a bump between the conductive via and second interconnect structure.

17. The method of claim 14, further including mounting a second semiconductor component over the first interconnect structure.

18. The method of claim 14, further including forming a redistribution layer between the conductive via and first semiconductor component.

19. The method of claim 14, further including:
mounting the first semiconductor component on a carrier prior to depositing the encapsulant;
removing a portion of the encapsulant and first semiconductor component to expose the conductive via; and
removing the carrier after forming the first interconnect structure.

20. A method of making a semiconductor device, comprising:
providing a semiconductor wafer having a plurality of semiconductor components separated by a peripheral region;
forming an opening in the peripheral region having a depth less than a thickness of the semiconductor wafer;
depositing a conductive material in the opening of the peripheral region of the semiconductor wafer to form a conductive via; and
singulating the semiconductor wafer through the conductive via in the peripheral region to provide a plurality of semiconductor components each having the conductive via.

21. The method of claim 20, further including:
mounting a first semiconductor component on a carrier;
depositing an encapsulant over the carrier around the first semiconductor component;
removing a portion of the encapsulant and first semiconductor component to expose the conductive via; and
forming a first interconnect structure over the encapsulant and first semiconductor component, the first interconnect structure being electrically connected to the conductive via.

22. The method of claim 21, further including mounting a second semiconductor component over the first interconnect structure.

23. The method of claim 21, further including forming a second interconnect structure over the encapsulant and first semiconductor component opposite the first interconnect structure, the second interconnect structure being electrically connected to the conductive via.

24. The method of claim 23, further including forming a bump between the conductive via and second interconnect structure.

25. The method of claim 20, further including forming a redistribution layer between the conductive via and first semiconductor component.
